(19) United States
(12) Patent Application Publication
(10) Pub. No.: US 2020/0135266 A1
(43) Pub. Date: Apr. 30, 2020

(54) RANDOM-ACCESS MEMORY WITH LOADED CAPACITANCE

(71) Applicant: INTEL CORPORATION, Santa Clara, CA (US)

(72) Inventors: Raghavan Kumar, Hillsboro, OR (US); Sasikanth Manipatruni, Portland, OR (US); Gregory Chen, Portland, OR (US); Huseyin Ekin Sumbul, Portland, OR (US); Phil Knag, Hillsboro, OR (US); Ram Krishnamurthy, Portland, OR (US); Ian Young, Portland, OR (US); Mark Bohr, Aloha, OR (US); Amrita Mathuriya, Portland, OR (US)

(73) Assignee: INTEL CORPORATION, Santa Clara, CA (US)

(21) Appl. No.: 16/175,059

(22) Filed: Oct. 30, 2018

(51) Int. Cl. G11C 11/412; H01L 27/11; H01L 49/02; G11C 11/419

(52) U.S. Cl. CPC G11C 11/412; G11C 11/419; H01L 28/40; H01L 27/1104

(57) ABSTRACT

A loaded capacitance static random-access memory (C-SRAM) is provided. The C-SRAM is configured to prevent full bit line discharge during a functional reads even where the number of bit cells on the bit lines is small. The C-SRAM includes one or more loaded capacitance structures that may take any of a variety of physical configurations designed to provide additional capacitance to the bit lines. For instance, the loaded capacitance structures may take the form of a MIM capacitor in which a ferroelectric layer is formed from one or more high K materials. In addition, the loaded capacitance structures may be positioned in a variety of locations within the C-SRAM, including the back end of line.

### BACKGROUND

Static random-access memory (SRAM) generally includes an array of bit cells that each persistently store 1 bit of data. In one configuration, each SRAM bit cell consists of six transistors. In this 6T configuration, four of the transistors are arranged to form a bistable latch. The bistable latch is capable of assuming one of two stable states—either a high-resistance state (HRS), which may be representative of an ‘off’ or ‘0’ state, or a low-resistance state (LRS), which may be representative of an ‘on’ or ‘1’ state. Each of these states corresponds to a value (0 or 1) of the bit of data stored in the SRAM bit cell. Further, in the 6T configuration, the remaining two transistors are coupled to the latch to provide switchable access to the latch as may be used during read and write operations involving the SRAM bit cell. The access transistors are coupled to a word line and two bit lines. The word line controls the access transistors, causing them to couple the bit lines to the latch during read and write operations and to decouple the bit lines from the latch at other times.

During a read or write operation involving SRAM, the bit lines are pre-charged to a state appropriate to implement the read or write operation, and the word line is activated (i.e., pulsed) to couple the latch to the bit lines for a duration of time. During a read operation, when the word line is activated the bit lines discharge to a voltage proportional to the state of the latch. A sense amplifier coupled to the bit lines detects the change in voltage on the bit lines and amplifies the change to a data signal having a value of 0 or 1. This data signal is stored in a buffer and/or provided to an output bus.

### BRIEF DESCRIPTION OF THE DRAWINGS

FIG. 1 is a schematic diagram of example SRAM that includes a compute-in memory (CIM) accelerator in accordance with some embodiments of the present disclosure.

FIG. 2 is a schematic diagram of example capacitance-loaded static random-access memory (C-SRAM) that includes loaded capacitance structures in accordance with some embodiments of the present disclosure.

FIG. 3 is a schematic diagram of an example C-SRAM bit cell coupled to a loaded capacitance structure in accordance with some embodiments of the present disclosure.

FIG. 4 is a cross-sectional view of an integrated circuit structure including an access transistor of an example C-SRAM bit cell with a loaded capacitance structure disposed in the back end of line (BEOL) of the C-SRAM in accordance with some embodiments of the present disclosure.

FIG. 5 is a cross-sectional view of an example loaded capacitance structure formed as a loaded capacitance stack including a single layer of a high-K dielectric having a dielectric constant greater than silicon dioxide, in accordance with some embodiments of the present disclosure.

FIG. 6 is a cross-sectional view of an example loaded capacitance structure formed as a loaded capacitance stack including a superlattice of high-K materials in accordance with some embodiments of the present disclosure.

FIG. 7 is flow diagram illustrating a method of forming an C-SRAM bit cell including a loaded capacitance structure in accordance with some embodiments of the present disclosure.

FIG. 8 is flow diagram illustrating a functional read operation executed using an C-SRAM including a loaded capacitance structure in accordance with some embodiments of the present disclosure.

FIG. 9 is a block diagram of a computing system implemented with C-SRAM formed using the techniques disclosed herein in accordance with some embodiments of the present disclosure.

FIG. 10 is a graph illustrating the impact of loaded capacitance (CBL) on bit line voltage (V_{BL}).

FIG. 11 is a graph illustrating relationships between bit line voltage and pulse width where the amounts of loaded capacitance is varied.

FIG. 12 is a graph illustrating relationships between bit line voltage and amounts of loaded capacitance where 2 bit functional reads are performed.

FIG. 13 is a graph illustrating relationships between bit line voltage and amounts of loaded capacitance where 4 bit functional reads are performed.

These and other features of the present embodiments will be understood better by reading the following detailed description, taken together with the figures herein described. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles, and some features may have surface topography or otherwise be non-smooth, given real-world limitations of fabrication processes. Further still, some of the features in the drawings may include a patterned and/or shaded fill, which is primarily provided to assist in visually differentiating the different features. In short, the figures are provided merely to show example structures.

### DETAILED DESCRIPTION

C-SRAM described herein includes loaded capacitance on the bit lines to prevent full bit line discharge during functional read operations with relatively long durations. This loaded capacitance can be disposed at a variety of locations coupled to the bit lines. In one example, the loaded capacitance takes the form of multiple capacitance structures disposed as a part of the bit cells of the C-SRAM. By being disposed as a part of the bit cells, these capacitance structures provide an additional benefit of requiring little to no additional space within the C-SRAM. In another example, the loaded capacitance takes the form of one or more capacitance structures coupled to the bit lines and disposed separately from the bit cells. In these and other examples, each capacitance structure is formed as a vertical interconnect access (VIA) and/or a capacitance stack with multiple layers. The layers include one or more dielectric layers disposed between two conductive layers. The one or more dielectric layers may be composed of high-K materials. These high-K materials may be arranged as a single layer or as multiple layers of high-K materials (e.g., superlattice of two or more alternating material layers). In some such embodiments, the superlattice enables more precise control of the amount of loaded capacitance when compared to other techniques.

General Overview

SRAM may include compute-in memory (CIM) accelerators to execute, concurrently with a read operation, selected calculations based on the electrical state of the SRAM. Examples of these selected calculations include calculations frequently needed by software (e.g., machine learning software) executed by a processor coupled to, but distinct and remote from, the SRAM. Such frequently needed calculations may include dot-products and absolute differences of vectors. By executing the selected calculations within the SRAM, CIM accelerators obviate the need to transfer data to the processor to execute the calculations. Thus, CIM accelerators generally improve overall performance of a computing system by decreasing interconnect communication and bandwidth consumption within the computing system.

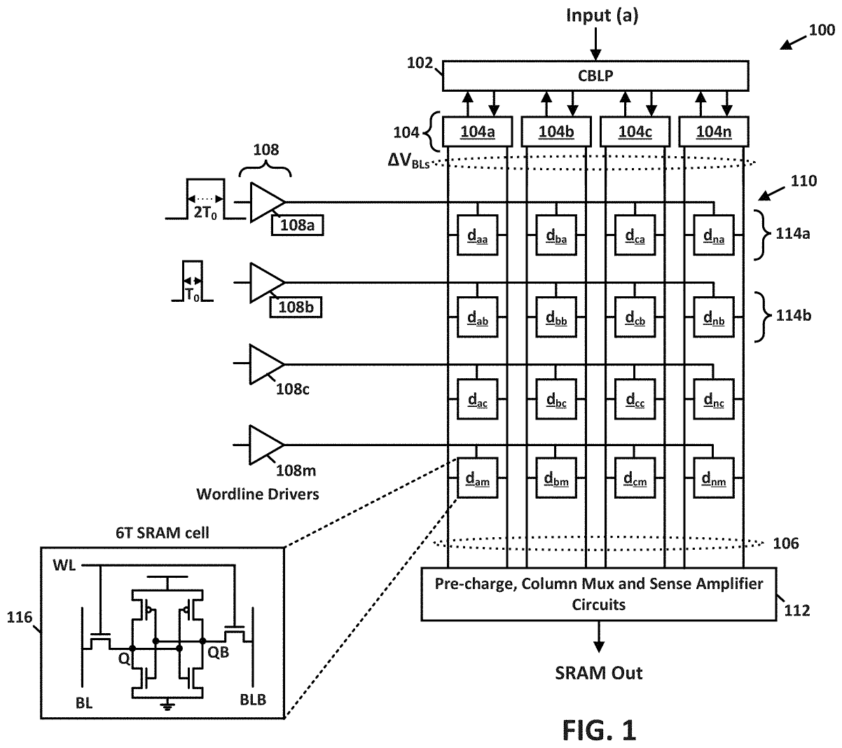

FIG. 1 illustrates an SRAM 100 that includes a CIM accelerator. As shown in FIG. 1, the SRAM 100 comprises a cross bit line processor 102, a plurality of bit line processors 104, a plurality of bit line pairs 106, a plurality of word line drivers 108, an array of SRAM bit cells 110, and sense amplifier, pre-charge, and column mux circuits 112. The plurality of bit line processors 104 includes bit line processors 104a through 104n. The plurality of word line drivers 108 includes word line drivers 108a through 108m. The array of SRAM bit cells 110 is arranged into columns and rows and includes bit cells that store electrical states that correspond to data values dₐₐ through dam. Each of the bit cells includes, for example, a 6T bit cell 116. The 6T bit cell 116 includes a latch with outputs Q and QB and connections for a word line (WL) and two bit lines (BL and BLB).

As shown in FIG. 1, the cross bit line processor 102, in conjunction with the plurality of bit line processors 104, implements the CIM accelerator. In one embodiment, the cross bit line processor 102 and the bit line processors 104 are analog circuits that sense voltage on the bit line and execute calculations directly on the voltage as part of a read operation. A read operation that is augmented in this way is referred to as a functional read. To enable functional reads, the SRAM 100 stores data within the array 110 in column major format, rather than a row major format. To execute a functional read of a word from the bit line, the SRAM 100 activates multiple word line drivers concurrently. For example, the SRAM 100 can be configured to activate the word line driver 108a and 108b concurrently. To ensure that the most significant bits have higher weight, the word line driver for the most significant bit is enabled for a longer duration than the word line driver for the least significant bit. For example, the SRAM 100 can be configured to enable the word line driver 108a for a duration of 2*T₀, and to enable the word line driver 108b for a duration of T₀. More generally, the SRAM 100 can be configured to enable the word line driver corresponding to bit for a duration of 2ⁱ*T₀, where the word line driver for the least significant bit₀ is enabled for a duration of T₀.

As with a standard read operation, prior to a functional read operation, the SRAM 100 is configured to pre-charge the plurality of bit line pairs 106 to the memory supply voltage V_{DD}. When the plurality of word line drivers 108 are activated, each bit line pair of the plurality of bit line pairs 106 discharges to a voltage proportional to the data values stored in the bit cells coupled to the bit line pair. As the activation durations are binary-weighted, the resulting bit line voltage drops (ΔV_{BLs}) is directly proportional to the binary words stored on the bit lines. In one example illustrated by FIG. 1, the SRAM 100 activates the word line driver 108a for a duration of 2*T₀ and activates the word line driver 108b for a duration of T₀. In this example, the discharge voltage of each of the plurality of bit lines pairs 106 is proportional to 2*(the data values stored in the bit cell coupled to the bit line pair in row 114a)+the data value stored in the bit cell coupled to the bit line pair in row 114b. Each of the voltage drops ΔV_{BLs} is directly used by the plurality of bit line processors 104 and the cross bit line processors 102 to perform, for example, basic machine learning calculations. In one such embodiment illustrated in FIG. 1, each of the plurality of bit line processors 104 performs an elementwise multiplication of an input (a) and the voltage drop on the bit line associated with the bit line processor, which produces a voltage corresponding to the multiplication of input (a) and the data values of the bit cells. The cross bit line processor 102 accumulates the voltages from the plurality of bit line processor 104 and produces a single output voltage, which corresponds to, for example, an accumulation operation in a digital processor (Σaᵢ*dᵢⱼ).

As described above, the functional reads performed by CIM accelerators require relatively long word line pulse widths. For example, where 50 picoseconds (ps) are required to sense accurately the least significant bit cells of a 4 bit word, a functional read of the 4 bit word requires a word line pulse width of 800 ps for the most significant bit cells. For SRAM including a relatively small array of bit cells, relatively long word line pulse widths can be problematic in that full bit line discharge can occur due to insufficient capacitance on the bit lines. Full bit line discharge occurs when bit cells coupled to the bit line fully discharge or discharge below a threshold level that prevents subsequent read operations from detecting a voltage change sufficient to generate a data signal.

Some possible solutions to prevent full bit line discharge include adding more bit cells to the bit lines and/or decreasing the width of word line pulses to, for example, 25 ps or less. These solutions have certain disadvantages. For example, adding more bit cells can result in large arrays that consume more physical space and power than are needed for some calculations (e.g., small dot products and other calculations associated with machine learning applications). Also, decreasing the width of word line pulses can result in insufficient time to successfully sense voltage changes needed to generate data signals.

Thus and in accordance with various embodiments of the present disclosure, techniques are disclosed for forming C-SRAM including a loaded capacitance. These capacitance loading techniques achieve a balance between word line pulse width and bit line capacitance to prevent full bit line discharge and improve precision (e.g., in the number of bits read) of functional read operations. In some embodiments, the capacitance loading techniques include depositing a loaded capacitance structure so that the capacitance structure is coupled to a bit line of the C-SRAM, distinct from other components of the C-SRAM. In other embodiments, the capacitance loading techniques include disposing a capacitance structure in association with, and coupled to, each bit cell. For example, the capacitance structure may be disposed in the BEOL as a VIA and/or a stack including at least one dielectric layer disposed between two conductive layers. Adding small, extra capacitance per bit cell increases the total discharge time of the bit line voltage when one or more rows are enabled during a functional read operation involving CIM accelerators.

In some embodiments, portions of loaded capacitance structures are formed with traditional dielectrics having a thickness of between 1 nanometer (nm) and 50 nm to reach a target capacitance (e.g., 10 aF-100 fF). In some such embodiments, the loaded capacitance structure may include a VIA and/or a metal-insulator-metal (MIM) capacitance structure. In some examples, MIM capacitance structures are formed as stacks of one or more layers of high-K materials disposed between two conductive layers. In these examples, the conductive layers are composed of conductive oxides (e.g., SRO, LSMO, Nb-STO) and metallic nitrides (e.g., TiN, TaN, etc.). The one or more layers of high-K materials may include TiO₂, BaO, La₂O₃, HfO₂, ZrO₂, Ta₂O₅, SrO, Y₂O₃, CaO, Al₂O₃, ZrSiO₄, HfSiO₄, MgO, and Si₃N₄. In other examples, MIM capacitance structures are formed as stacks with one or more layers of high-K materials disposed as a superlattice. In some of these examples, the superlattice is composed of alternating layers of PbTiO₃ and SrTiO₃ (also designated herein as PbTiO₃/SrTiO₃).

Determining a suitable amount of loaded capacitance to provide within the C-SRAM requires consideration of several factors. These factors include the precision of the functional read (e.g., the number of bits to be read) and it associated word line pulse width, the lower bound of voltage that can be sensed by C-SRAM circuitry (i.e., its V_{threshold}), and the smallest voltage drop interval detectable by C-SRAM circuitry (i.e. its resolution). A suitable amount of loaded capacitance prevents full bit line discharge and also allows for a range of voltage drops of sufficient magnitude to allow the C-SRAM circuitry (e.g., the plurality of bit line processors 104 and the cross bit line processor 102) to sense all possible combinations of data values in view of its resolution. Too little capacitance results in full bit line discharge during a functional read. Too much capacitance results in an insufficient range of voltage drops given the resolution of the C-SRAM. Thus, the range of voltages on the bit line should satisfy the following inequality at all times during a functional read: V_{threshold}<V_{BL}<V_{DD}. The embodiments disclosed herein enable functional reads that meet these conditions.

Further, in at least some embodiments, C-SRAM enables functional reads that are well suited to machine learning applications, such as functional reads that calculate dot products, accumulations, and matrix arithmetic. As these basic machine learning operations are deeply embedded within the C-SRAM memory array, use of C-SRAM in some computer systems substantially improves performance, both in terms of calculation speed and energy consumption, of the computer system.

Note that, as used herein, the expression “X includes at least one of A or B” refers to an X that may include, for example, just A only, just B only, or both A and B. To this end, an X that includes at least one of A or B is not to be understood as an X that requires each of A and B, unless expressly so stated. For instance, the expression “X includes A and B” refers to an X that expressly includes both A and B. Moreover, this is true for any number of items greater than two, where “at least one of” those items is included in X. For example, as used herein, the expression “X includes at least one of A, B, or C” refers to an X that may include just A only, just B only, just C only, only A and B (and not C), only A and C (and not B), only B and C (and not A), or each of A, B, and C. This is true even if any of A, B, or C happens to include multiple types or variations. To this end, an X that includes at least one of A, B, or C is not to be understood as an X that requires each of A, B, and C, unless expressly so stated. For instance, the expression “X includes A, B, and C” refers to an X that expressly includes each of A, B, and C. Likewise, the expression “X included in at least one of A or B” refers to an X that may be included, for example, in just A only, in just B only, or in both A and B. The above discussion with respect to “X includes at least one of A or B” equally applies here, as will be appreciated.

Use of the techniques and structures provided herein may be detectable using tools such as: electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDS); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, in some embodiments, such tools may indicate an RRAM cell including a tunnel source transistor, such as a tunnel source MOSFET, as variously described herein. For instance, a cross-section analysis of a bit cell array could be performed to determine whether a loaded capacitance structure is coupled to a bit line in the BEOL, as can be understood based on this disclosure. In some embodiments, the techniques and structures described herein may be detected based on the benefits derived therefrom, such as being able to execute an 8 bit functional read within the footprint of a standard SRAM due to the use of the loaded capacitance structures described herein. Numerous configurations and variations will be apparent in light of this disclosure.

For convenience of explanation C-SRAM bit cells are described as 6T bit cells. However, other configurations of bit cells (e.g., 4T/8T/10T bit cells among others) fall within the scope of this disclosure.

Architecture

As explained above with reference to FIG. 1, a functional read involves concurrently activating multiple word line drivers of the plurality of word line drivers 108. In scenarios where the bit line capacitance is insufficient and/or the word line pulse width (2ⁱ*T₀) is too long, the bit line voltage can discharge to low voltages or even to ground. In such cases, the low bit line voltage makes it difficult to sense data values and/or perform analog computations such as multiplication and accumulation.

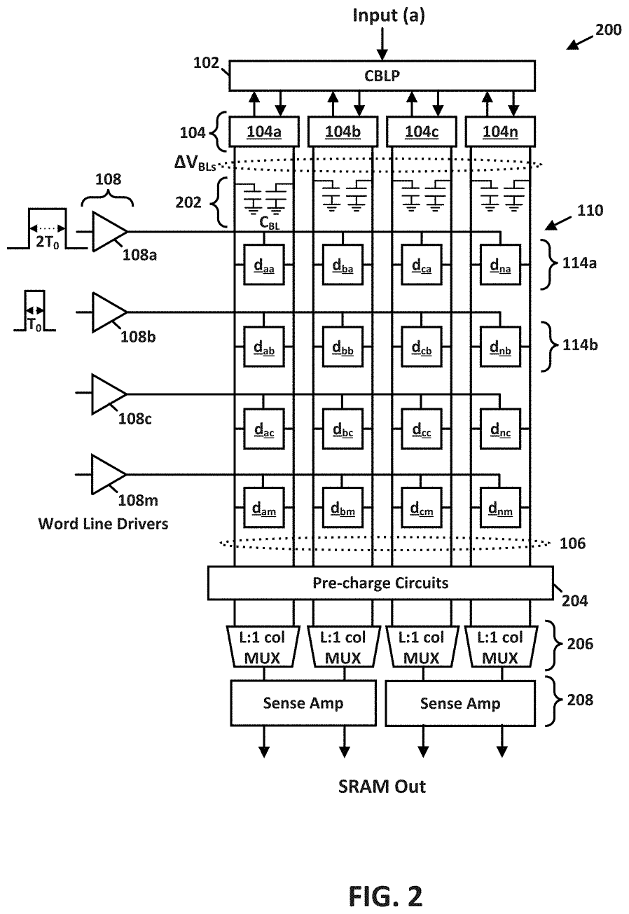

FIG. 2 illustrates an C-SRAM 200 configured to prevent full bit line discharge even where the number of bit cells on the bit lines is small. As shown, the C-SRAM 200 includes several components described above with reference to the SRAM 100. As such, the descriptions of those components apply equally to the C-SRAM 200. More specifically, the components of the C-SRAM 200 described above include the cross bit line processor 102, the plurality of bit line processors 104, the plurality of bit line pairs 106, the plurality of word line drivers 108, and the array of bit cells 110. In addition, the C-SRAM 200 includes a plurality of loaded capacitance structures 202, pre-charge circuits 204, a plurality of MUX circuits 206, and a plurality of sense amplifiers 208.

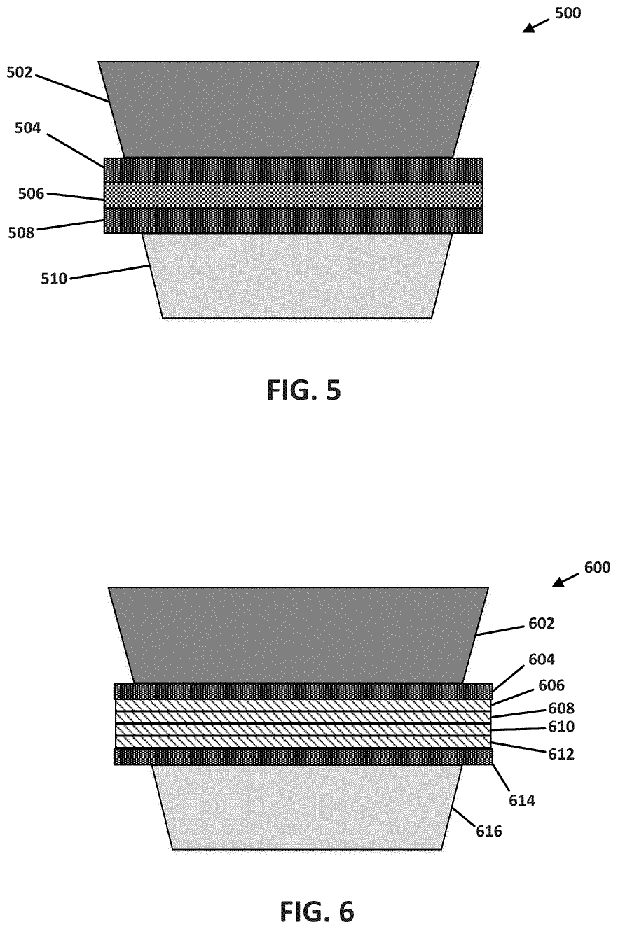

The loaded capacitance structures 202 may take any of a variety of physical configurations designed to provide additional capacitance to one or more bit lines of the plurality of bit line pairs 106. Two of these configurations are described further below with reference to FIGS. 5 and 6. However, in all cases the physical configurations of the loaded capacitance structures 202 are different from the physical configurations of the bit cells in the array of bit cells 110.

As shown in FIG. 2, each of the plurality of loaded capacitance structures 202 is coupled to one bit line pair of the plurality of bit line pairs 106. The plurality of loaded capacitance structures 202 augment the capacitance of the plurality of bit lines 106, thereby preventing full bit line discharge during functional reads. For instance, in the particular case of the C-SRAM 200, the plurality of loaded capacitance structures 202 provide a total capacitance of between 40 fF and 70 fF (e.g., 50 fF) to support a functional read.

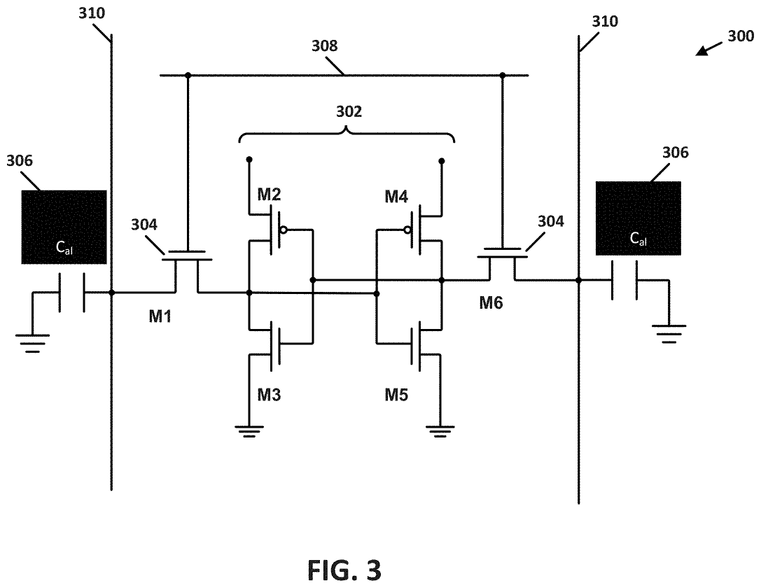

As shown in FIG. 2, the loaded capacitance structures 202 are distinct from any given bit cell of the array of bit cells 110. However, in other embodiments capacitance structures are a part of one or more of the bit cells of the array of bit cells 110. A 6T bit cell in accordance with one such embodiment is illustrated in FIG. 3.

More specifically, FIG. 3 illustrates a C-SRAM bit cell 300 that includes a latch 302, two access transistors 304, and two loaded capacitance structures 306. As shown in FIG. 3, each of the access transistors 304 is coupled to a word line 308 and one of two bit lines 310. Each of the capacitance structures 306 is coupled to, and a part of, the C-SRAM bit cell 300 and is also coupled to one of the two bit lines 310. The latch 302 includes four transistors M2-M5. The two access transistors 304 include M1 and M6.

As shown in FIG. 3, each of the capacitance structures 306 contributes to the overall capacitance of the bit line 310 to which it is coupled. The capacitance structures 306 may be assembled using a variety of techniques and materials. Examples of these techniques and materials are described further below with reference to FIGS. 5-7.

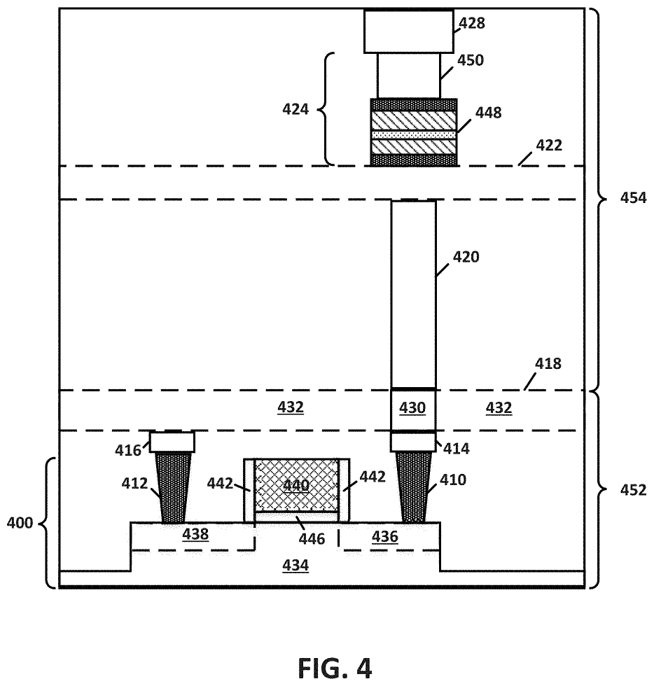

As illustrated in FIG. 3, the capacitance structures 306 are coupled to the C-SRAM bit cell 300 at interconnects between the access transistors 304 and the two bit lines 310. More detail regarding the physical layout of this portion of the C-SRAM bit cell 300 is provided in FIG. 4. FIG. 4 is cross-sectional view of a portion of an example C-SRAM bit cell with loaded capacitance, such as the C-SRAM bit cell 300, in accordance with some embodiments. As shown in FIG. 4, the portion of the C-SRAM bit cell 300 includes an access transistor 400 (e.g., one of the access transistors 304), a drain contact 410, a source contact 412, a first VIA 414, a second VIA 416, a first metal layer 418, a third VIA 420, a second metal layer 422, a capacitance structure 424 (e.g., one of the capacitance structures 306), and a third metal layer 428. The first metal layer 418 includes a first color 430 and a second color 432. The access transistor 400 includes a substrate 434, a drain region 436, a source region 438, a gate electrode 440, gate sidewall spacers 442, and gate dielectric 446. The loaded capacitance structure 424 includes a loaded capacitance stack 448 and a fourth VIA 450.

As shown in FIG. 4, the first and second VIAs 414 and 416 respectively electrically couple the drain and source contacts 410 and 412 to the first and second colors 430 and 432 of the first metal layer 418. The first metal layer 418 electrically couples the access transistor 400 to other parts of the C-SRAM bit cell 300. The third VIA 420 electrically couples the access transistor 400 to the second metal layer 422, which houses a bit line, such as one bit line of the pairs of bit lines 310. As shown, the second metal layer 422 is coupled to the capacitance structure 424, which is in turn electrically coupled to the third metal layer 428. More specifically, in the example shown in FIG. 4, the capacitance stack 448 is electrically coupled to the second metal layer 422 and the fourth VIA 450 is electrically coupled to the third metal layer 428, which is usually a ground. The various components illustrated in FIG. 4 collectively electrically couple the capacitance structure 424 to both a bit line and the access transistor 400, thereby establishing the capacitance structure 424 as part of a bit cell.

As shown in FIG. 4, the capacitance structure 424 is disposed within one or more interconnect layers of the back end of line 454 rather than the device layer of the front end of line 452. More specifically, in this example embodiment, the capacitance structure 424 is disposed between the second and third metal layers 422 and 428, or within one or both of these metal layers 422 and 428. Disposing the capacitance structure 424 at this location or another location within the back end of line 454 (e.g., between or within metal layers 6 and/or 7, or between or within metal layers 8 and/or 9) enables some embodiments to be housed within the physical footprint of standard SRAM. However, the scope of the present disclosure is not limited to this particular arrangement. In other embodiments, the capacitance structure 424 is disposed within the front end of line 452. In still other embodiments, the capacitance structure 424 is disposed at any of various locations where two adjacent metal wires intersect within the C-SRAM. For instance, the capacitance structure 424 may be disposed between the M2 and M3 transistors or between the M3 and M4 transistors as described above with reference to FIG. 3. Other potential locations for the capacitance structure 424 within the various metal interconnect layers making up the back end of line or elsewhere in the overall integrated circuit structure (even in the device layer) will be apparent in view of this disclosure.

In some embodiments, the fourth VIA 450, in conjunction with the loaded capacitance stack 448, supplies the target amount of capacitance. However, the bulk of the target amount of capacitance is supplied by the loaded capacitance stack 448.

In some embodiments, the capacitance structure 424 includes a stack, with or without a VIA, disposed to include several layers. FIG. 5 illustrates a cross-sectional view of an example loaded capacitance stack 500 formed in this manner in accordance with some embodiments. As shown in FIG. 5, the loaded capacitance stack 500 includes three layers 504-508 disposed between two contacts 502 and 510. In some embodiments, layers 504 and 508 are conductive electrodes, such as electrodes made up of oxide compounds and nitride compounds (e.g. O/N electrodes, which may include oxides, nitrides, or both) that resist fatigue. In some such embodiments, the layer 506 includes one of the following dielectrics: TiO₂, BaO, La₂O₃, HfO₂, ZrO₂, Ta₂O₅, SrO, Y₂O₃, CaO, Al₂O₃, ZrSiO₄, and HfSiO₄. Each of layers 504 through 508 may have a thickness of between 1 nm and 50 nm and may collective produce a target capacitance of between 10 aF-100 fF.

FIG. 6 illustrates a cross-sectional view of an example loaded capacitance stack 600 including a superlattice of high-K materials in accordance with some embodiments. As shown in FIG. 6, the loaded capacitance stack 600 includes seven layers 604-614 disposed between two contacts 602 and 616. In some embodiments, layers 604 and 614 are conductive electrodes, such as O/N electrodes that resist fatigue. Each of layers 604 and 614 may have a thickness of between 1 nm and 50 nm.

In some embodiments, each of layers 604-612 is composed of a PbTiO₃/SrTiO₃ superlattice (a bilayer structure including a first layer of PbTiO₃ and a second layer of SrTiO₃) that has dielectric properties. Collectively, the layers 604-612 function as a dielectric layer with sufficient K to generate the targeted amount of capacitance within the loaded capacitance stack 600. In some such embodiments, each of the layers 604-614 is composed of a PbTiO₃/SrTiO₃ film having a thickness of between 1 nm and 50 nm.

In other embodiments, the layers of the capacitance stack 600 are formed with other characteristics. Some examples of the capacitance stack 600 include fewer or greater than seven layers. In these examples, targeted amounts of capacitance can be built with enhanced precision by layering forming a particular number of dielectric layers within the capacitance stack 600.

The contacts 502, 510, 602, and 616, in some embodiments, include one or more metals such as of tantalum (Ta), tungsten (W), platinum (Pt), bismuth (Bi), iridium (Ir), or manganese (Mn).

Returning to FIG. 4, in some embodiments, the access transistor 400 is formed on and from the substrate 434. However, in other embodiments, the access transistor 400 is formed above the substrate 434 but are not formed from the substrate 434 (e.g., the transistor is formed using different material formed on or above substrate 434). In some embodiments, access transistor 400 is a metal-oxide-semiconductor field-effect transistors (MOSFET) device, for example. In some embodiments, the access transistor 400 may be a planar or a nonplanar transistor, or a combination of both. Nonplanar transistors include finned transistors (such as FinFET transistors, which may be double-gate or tri-gate transistors) and gate-all-around (GAA) transistors (e.g., where the gate structure wraps around one or more nanowires or nanoribbons). Note that, areas within the portion of the example C-SRAM bit cell illustrated in FIG. 4 can be filled with any suitable dielectric material (e.g., silicon oxide and/or silicon nitride).

Methodology

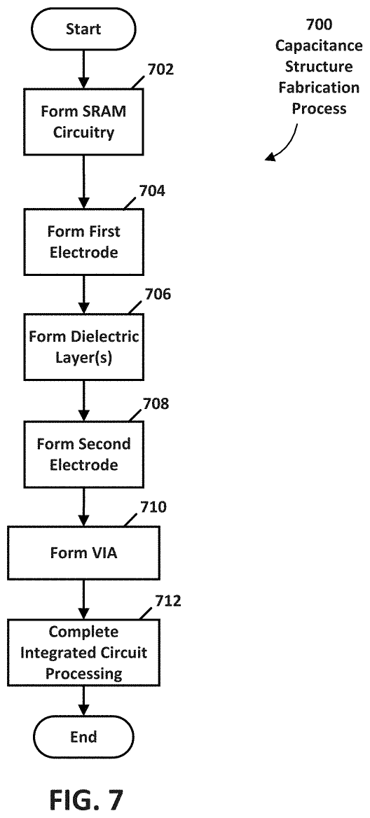

FIG. 7 illustrates a fabrication process 700 of forming an integrated circuit (IC), such as the C-SRAM, C-SRAM bit cells, or other components thereof, including at least one loaded capacitance structure, in accordance with some embodiments. FIGS. 4-6 illustrate cross-sectional views of example IC structures formed when carrying out acts 704-712 of the process 700 of FIG. 7, in accordance with some embodiments. The cross-sectional views in FIGS. 4-6 are through the loaded capacitance structure to illustrate the different layers included therein, including the loaded capacitance stacks described herein.

Note that deposition or epitaxial growth techniques (or more generally, additive processing) where described herein can use any suitable techniques, such as chemical vapor deposition (CVD), physical vapor deposition (PVD), atomic layer deposition (ALD), and/or molecular beam epitaxy (MBE), to provide some examples. Also note that etching techniques (or more generally, subtractive processing) where described herein can use any suitable techniques, such as wet and/or dry (or plasma) etch processing which may be isotropic (e.g., uniform etch rate in all directions) or anisotropic (e.g., etch rates that are orientation dependent), and which may be non-selective (e.g., etches all exposed materials at the same or similar rates) or selective (e.g., etches different exposed materials at different rates). Further note that other processing may be used to form the integrated circuits structures described herein as will be apparent in light of this disclosure, such as hard masking, patterning or lithography (via suitable lithography techniques, such as, e.g., photolithography, extreme ultraviolet lithography, x-ray lithography, or electron beam lithography), planarizing or polishing (e.g., via chemical-mechanical planarization (CMP) processing), doping (e.g., via ion implantation, diffusion, or including dopant in the base material during formation), and annealing, to name some examples.

The fabrication process 700 of FIG. 7 starts with forming 702 SRAM circuitry, such as the circuitry described above with reference to FIG. 2, in accordance with some embodiments. This SRAM circuitry can include the cross bit line processor 102, the plurality of bit line processors 104, the plurality of bit line pairs 106, the plurality of word line drivers 108, the array of bit cells 110, the pre-charge circuits 204, the plurality of MUX circuits 206, and the plurality of sense amplifiers 208. Much of the SRAM circuitry formed in the act 702 is disposed in the front end of line of the IC, however this is not a requirement.

The fabrication process 700 of FIG. 7 continues with forming 704 a first electrode, such as the first electrode structures 508 or 614 described above in the example structures of FIGS. 5 and 6, in accordance with some embodiments. As shown in FIG. 4, the first electrode structure, which is a layer within the capacitance stack 448, is formed within the back end of line 454 above the second metal layer 422, which houses a bit line. In some embodiments, there are one or more intervening layers or features between the second metal layer 422 and the first electrode structure, while in other embodiments, the first electrode structure is formed directly on second metal layer 422 (such that they are in physical contact). In embodiments including intervening layers or features between the first electrode structure and the second metal layer 422, such intervening layers may include one or more conductive interconnects and/or one or more seed layers. The first electrode structure can be formed using any suitable techniques. For instance, in some embodiments, the first electrode structure is formed by blanket depositing the one or more layers included in the first electrode structure and patterning/etching the one or more layers to the desired size and shape, for example.

The fabrication process 700 of FIG. 7 continues with forming 706 one or more dielectric layers, such as the layer 506 or the layers 606-612, in accordance with some embodiments. These layers can be formed using any suitable techniques. For instance, in some embodiments, the layers may be blanket deposited (at least in an area over the first electrode structure), for example.

The fabrication process 700 of FIG. 7 continues with forming 708 a second electrode, such as the second electrode structures 504 or 604 described above in the example structures of FIGS. 5 and 6, in accordance with some embodiments. The second electrode structure can be formed using any suitable techniques. For instance, in some embodiments, the second electrode structure is formed by blanket depositing the one or more layers included in the second electrode structure and patterning/etching the one or more layers to the desired size and shape, for example.

The fabrication process 700 of FIG. 7 continues with forming 710 a VIA, such as the fourth VIA 450 described above in the example structure of FIG. 4, in accordance with some embodiments. The VIA can be formed using any suitable techniques.

The fabrication process 700 of FIG. 7 concludes with completing 712 the IC processing. This IC processing can include forming one or more metallization layers, such as the third metal layer 428, and/or interconnecting other devices and features with in the IC.

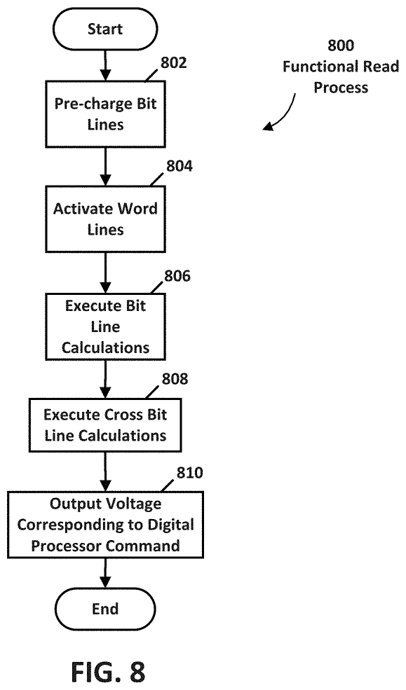

FIG. 8 illustrates a functional read process 800 of executing a functional read within a C-SRAM, in accordance with some embodiments. Process 800 starts with pre-charging 802 bit lines to a supply voltage (e.g., 0.9V). In some embodiments, the act 802 is performed by pre-charge circuits, such as the pre-charge circuits 204 illustrated above with reference to FIG. 2. In these embodiments, the bit lines pre-charged include the bit lines 106.

The functional read process 800 continues with activating 804 word lines. In some embodiments, the act 804 is performed by word line drivers, such as the word line drivers 108 illustrated above with reference to FIG. 2. Further, in some such embodiments, while active the word line drivers 108 transmit electrical pulses with widths ranging from 50 ps (for the bit cells storing the least significant bits—e.g., bit cells dam through dam described above with reference to FIG. 2) to (2ⁱ*50 ps) (for bit cells storing the most significant bits—e.g., bit cells dₐₐ through dₐₐ described above with reference to FIG. 2). Activating 804 the word lines will cause a voltage drop in the pre-charged bit lines that is proportional to, and therefore reflects, the data values stored in the bit cells coupled to the bit lines.

The functional read process 800 continues with executing 806 bit line calculations. In some embodiments, the act 806 is performed by bit line processors, such as the bit line processors 104 described above with reference to FIG. 2. In some such embodiments, the bit line processors perform calculations using an input and the analog voltages present on the bit lines. One example of these calculations includes an elementwise multiplication of the input and the voltage change on the bit lines coupled to the bit line processor.

The functional read process 800 continues with executing 808 cross bit line calculations. In some embodiments, the act 808 is performed by a cross bit line processor, such as the cross bit line processor 102 described above with reference to FIG. 2. In some such embodiments, the cross bit line processor performs a calculation (e.g., an accumulation) using an input the analog voltages supplied to the cross bit line calculations by the bit line processors.

The functional read process 800 concludes with outputting 810 the result of the calculation performed by the cross bit line processor. In some embodiments, the act 810 is performed by the cross bit line processor and involves placing the result (in the form of an analog voltage corresponding to a digital processor command (e.g., an accumulation operation)) on an interconnect between the C-SRAM and a digital processor.

Note that the processes 702-710 of the fabrication process 700 and the processes 802-810 of the functional read process 800 are shown in a particular order for ease of description, in accordance with some embodiments. However, one or more of the processes 702-710 and the processes 802-810 can be performed in a different order or need not be performed at all, in other embodiments. Other variations as can be understood based on this disclosure may also occur. Numerous variations on the fabrication process 700, the functional read process 800, and the techniques described herein will be apparent in light of this disclosure.

Example System

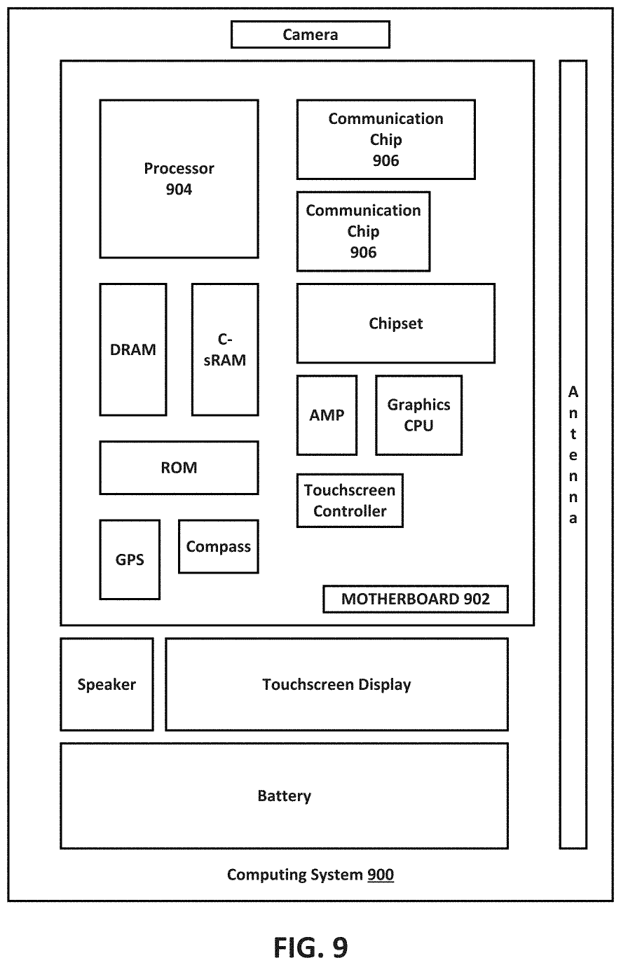

FIG. 9 illustrates a computing system 900 implemented with integrated circuit structures and/or C-SRAM with loaded capacitance structures as disclosed herein, in accordance with some embodiments. As can be seen, the computing system 900 houses a motherboard 902. The motherboard 902 can include a number of components, including, but not limited to, a processor 904 and at least one communication chip 906, each of which can be physically and electrically coupled to the motherboard 902, or otherwise integrated therein. As will be appreciated, the motherboard 902 may be, for example, any printed circuit board, whether a main board, a daughterboard mounted on a main board, or the only board of system 900, etc.

Depending on its applications, computing system 900 can include one or more other components that may or may not be physically and electrically coupled to the motherboard 902. These other components can include, but are not limited to, volatile memory (e.g., DRAM or other types of RAM, C-SRAM, etc.), non-volatile memory (e.g., ROM, etc.), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 900 can include one or more integrated circuit structures or devices formed using the disclosed techniques in accordance with an example embodiment. In some embodiments, multiple functions can be integrated into one or more chips (e.g., for instance, note that the communication chip 906 can be part of or otherwise integrated into the processor 904).

The communication chip 906 enables wireless communications for the transfer of data to and from the computing system 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 can implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 900 can include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing system 900 includes an integrated circuit die packaged within the processor 904. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 906 also can include an integrated circuit die packaged within the communication chip 906. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability can be integrated directly into the processor 904 (e.g., where functionality of any chips 906 is integrated into processor 904, rather than having separate communication chips). Further note that processor 904 can be a chip set having such wireless capability. In short, any number of processor 904 and/or communication chips 906 can be used. Likewise, any one chip or chip set can have multiple functions integrated therein.

In various implementations, the computing system 900 can be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Benefits According to Some Embodiments

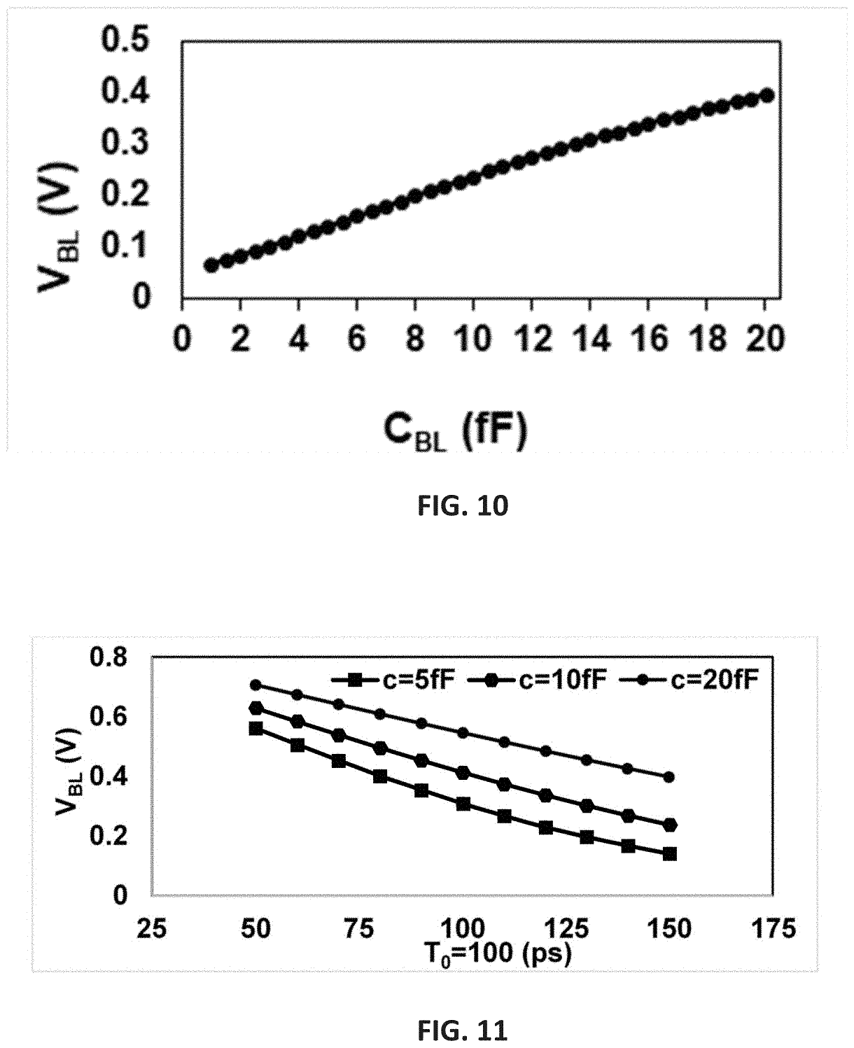

Simulation results illustrate the benefits provided by the embodiments disclosed herein. FIG. 10 is a graph illustrating the impact of loaded capacitance (C_{BL}) on bit line voltage (V_{BL}). In this simulation of a C-SRAM, amounts of loaded capacitance quantified on the x-axis of the graph were coupled to a bit cell array in 10 nm process. The bit lines were precharged to a supply voltage of 0.9V. As can be seen with reference to the y-axis, without loaded capacitance, the bit lines discharge to low voltages (<0.1V). However, the discharge voltage level rises proportionally to the amount of added capacitance. Thus, the loaded capacitance helps to sample a slow discharging slope, thereby improving the precision, while also reducing the voltage swing resulting in energy savings.

The loaded capacitance on the bit line also helps to relax the constraints on word line pulse widths. In general, to discharge the bit line voltage less, pulse widths should be sufficiently low (T₀˜25 ps). Generating tiny pulses on-chip can be challenging and data values sensed via tiny pulses suffer from jitter and rise/fall time issues. However, loaded capacitance on the bit line helps to reduce the voltage swing (ΔV_{BL}) for the same pulse width as shown in FIG. 11. FIG. 11 is a graph illustrating relationships between bit line voltage and pulse width where the amounts of loaded capacitance is varied between three amounts (i.e. 5 fF, 10 fF, and 20 fF). As can be seen, for example, at a pulse width of 100 ps, the bit line voltage swing is almost 37% lower where the amount of loaded capacitance=10 fF as compared to where the amount of loaded capacitance=5 fF. In other words, to result in the same bit line voltage, the pulse width of T₀ must be constrained to about 60 ps as opposed to a 100 ps.

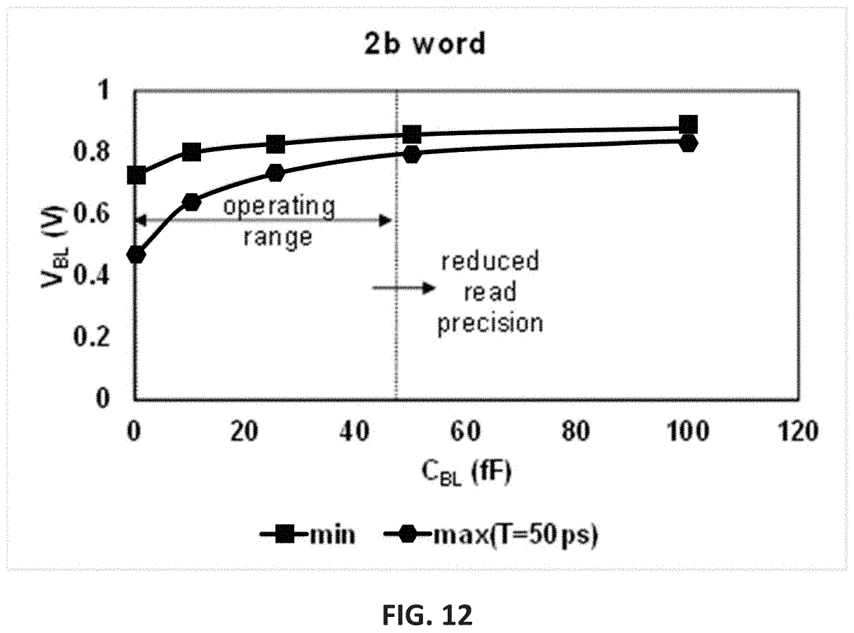

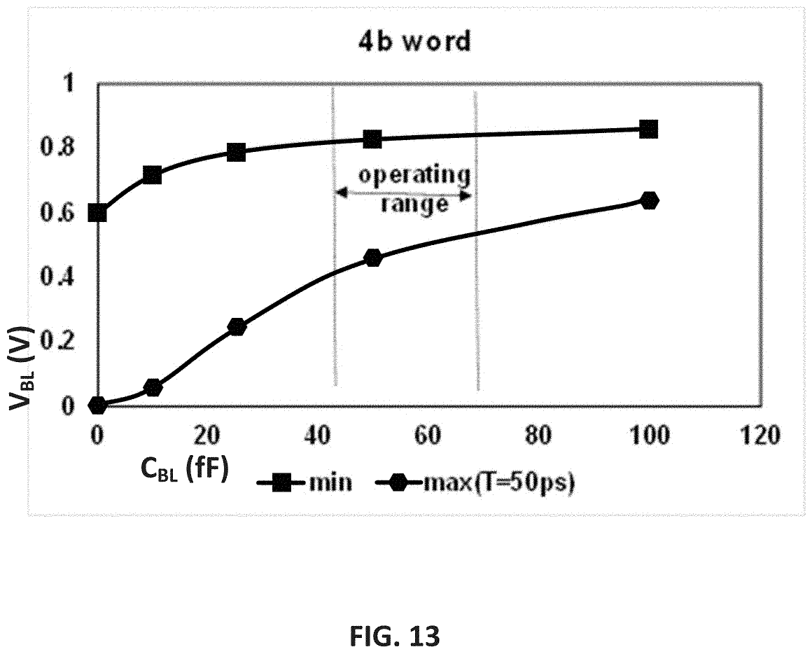

FIGS. 12 and 13 are graphs that collectively illustrate the impact of loaded capacitance on functional read precision (i.e., the number of bits included in a functional read). More specifically, FIGS. 12 and 13 illustrate operating ranges of loaded capacitance that enable safe, successful functional reads of varying precisions.

More specifically, FIG. 12 is a graph illustrating relationships between bit line voltage and amounts of loaded capacitance where 2 bit functional reads are performed on bit cells storing words indicated by a minimum voltage drop (for word=2′b11) and a maximum voltage drop (for word=2′b00). As seen in FIG. 12 with reference to the reduced read precision range, the maximum range of loaded capacitance is limited by the reduced voltage range between the minimum voltage drop and the maximum voltage drop. However, there is no minimum range on the loaded capacitance, as there is enough capacitance on the bit line to support a 2 bit voltage drop. In other words, as indicated by FIG. 12, the operating range of a 2 bit functional read includes SRAM configurations with no loaded capacitance.

However, the benefit of loaded capacitance becomes apparent for higher precision functional reads, such as the simulated functional reads that are the basis of the information presented in FIG. 13. FIG. 13 is a graph illustrating relationships between bit line voltage and amounts of loaded capacitance where 4 bit functional reads are performed on bit cells storing words indicated by a minimum voltage drop (for word=4′b1111) and a maximum voltage drop (for word=4′b0000). As seen in FIG. 13 with reference to the operating range, the amount of loaded capacitance needed to support a 4 bit functional read is in the range of approximately 40 fF-70 fF. The lower bound on the operating range is needed because a voltage drop on the bit line below approximate 0.3V may not be sensed. The upper bound on the operating range is needed because too much loaded capacitance may restrict the range of potential voltage drops to a point where it is difficult to reliably sample all possible bit combinations (number of possible words=24, for a 4 bit word). Given the relationships present in FIGS. 12 and 13, one can reasonably conclude that the minimum amount of loaded capacitance needed to support an 8 bit functional read is approximately 50 fF or 200 aF per bit cell.

### Further Example Embodiments

The following examples pertain to further embodiments, from which numerous permutations and configurations will be apparent.

Example 1 is an integrated circuit including at least one memory device. The integrated circuit includes an array of SRAM bit cells coupled to one or more bit lines. The integrated circuit includes at least one capacitance structure coupled to the one or more bit lines. The at least one capacitance structure is in a back end of line of the integrated circuit.

Example 2 includes the subject matter of Example 1, wherein the at least one capacitance structure includes a plurality of capacitance structures and each capacitance structure of the plurality of capacitance structures is coupled to a corresponding SRAM bit cell of the array of SRAM bit cells.

Example 3 includes the subject matter of either Example 1 or Example 2, wherein the at least one capacitance structure includes a stack of layers.

Example 4 includes the subject matter of Example 3, wherein the stack of layers includes a first conductive layer including an oxide compound and a nitride compound; a second conductive layer including the oxide compound and the nitride compound; and at least one layer including a high-K dielectric between the first conductive layer and the second conductive layer.

Example 5 includes the subject matter of Example 4, wherein the at least one layer includes one or more of TiO₂, BaO, La₂O₃, HfO₂, ZrO₂, Ta₂O₅, SrO, Y₂O₃, CaO, Al₂O₃, ZrSiO₄, HfSiO₄, MgO, and Si₃N₄.

Example 6 includes the subject matter of either Example 4 or Example 5, wherein the at least one layer includes oxygen and one or more of titanium, barium, lanthanum, hafnium, zirconium, tantalum, strontium, yttrium, calcium, aluminum, and magnesium.

Example 7 includes the subject matter of any of Examples 4-6, wherein the at least one layer includes oxygen, silicon, and one or more of hafnium and zirconium, or nitrogen and silicon.

Example 8 includes the subject matter of any of Examples 4-7, wherein the at least one layer includes a plurality of superlattice sub-layers, the plurality including first and second sub-layers each including a superlattice structure with high-K dielectric properties.

Example 9 includes the subject matter of Example 8, wherein the superlattice structure for each of the first and second sub-layers includes a bilayer structure of PbTiO₃ and SrTiO₃.

Example 10 includes the subject matter of any of Examples 3-9, wherein each layer of the stack of layers has a thickness of between 1 nm and 50 nm.

Example 11 includes the subject matter of any of Examples 2-10, wherein an amount of capacitance provided by the at least one capacitance structure is sufficient to prevent full discharge of the one or more bit lines during a functional read spanning more than 150 picoseconds.

Example 12 includes the subject matter of any of Examples 2-11, wherein an amount of capacitance provided by the at least one capacitance structure is between 10 aF and 100 fF.

Example 13 includes the subject matter of Example 12, wherein the amount of capacitance provided by the at least one capacitance structure is between 40 fF and 70 fF.

Example 14 includes the subject matter of either Example 12 or Example 13, wherein the amount of capacitance provided by the at least one capacitance structure is between 30 aF and 100 aF.

Example 15 is a capacitance-loaded static random-access memory (C-SRAM) including the integrated circuit of Example 1.

Example 16 is a processor including the C-SRAM of Example 15.

Example 17 is a capacitance-loaded static random-access memory (C-SRAM). The C-SRAM includes an array of SRAM bit cells coupled to one or more bit lines. The C-SRAM includes a plurality of capacitance structures. In the C-SRAM each capacitance structure of the plurality of capacitance structures is coupled to a corresponding SRAM bit cell of the array of SRAM bit cells.

Example 18 includes the subject matter of Example 17, wherein each capacitance structure of the plurality of capacitance structures is disposed in a back end of line of the C-SRAM.

Example 19 includes the subject matter of either Example 17 or Example 18, wherein an amount of capacitance provided by each capacitance structure of the plurality of capacitance structures is between 10 aF and 100 fF.

Example 20 includes the subject matter of any of Examples 17-19, wherein an amount of capacitance provided by the plurality of capacitance structures is between 10 aF and 100 fF.

Example 21 includes the subject matter of Example 20, wherein the amount of capacitance provided by the plurality of capacitance structures is between 30 aF and 100 aF.

Example 22 is a method of forming a capacitance-loaded static random-access memory (C-SRAM) bit cell. The method includes forming an access transistor in a front end of line of the C-SRAM. The method includes forming at least one interconnect coupled to the access transistor. The method includes forming a metal layer coupled to the at least one interconnect, the metal layer housing at least one bit line. The method includes forming, in a back end of line of the C-SRAM, a capacitance structure coupled to the metal layer.

Example 23 includes the subject matter of Example 22, wherein forming the capacitance structure includes forming a plurality of capacitance structures.

Example 24 includes the subject matter of Example 23, wherein forming the plurality of capacitance structures includes forming each capacitance structure of the plurality of capacitance structures to include a plurality of layers.

Example 25 includes the subject matter of Example 24, wherein forming each capacitance structure to include the plurality of layers includes forming each layer of the plurality of layers to have a thickness of between 1 nm and 50 nm.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner and may generally include any set of one or more limitations as variously disclosed or otherwise demonstrated herein.

What is claimed is:

1. An integrated circuit comprising:
an array of SRAM bit cells coupled to one or more bit lines; and
at least one capacitance structure coupled to the one or more bit lines and in a back end of line of the integrated circuit.

2. The integrated circuit of claim 1, wherein the at least one capacitance structure comprises a plurality of capacitance structures and each capacitance structure of the plurality of capacitance structures is coupled to a corresponding SRAM bit cell of the array of SRAM bit cells.

3. The integrated circuit of claim 1, wherein the at least one capacitance structure comprises a stack of layers.

4. The integrated circuit of claim 3, wherein the stack of layers comprises:
a first conductive layer comprising an oxide compound and a nitride compound;
a second conductive layer comprising the oxide compound and the nitride compound; and
at least one layer comprising a high-K dielectric between the first conductive layer and the second conductive layer.

5. The integrated circuit of claim 4, wherein the at least one layer comprises one or more of TiO₂, BaO, La₂O₃, HfO₂, ZrO₂, Ta₂O₅, SrO, Y₂O₃, CaO, Al₂O₃, ZrSiO₄, HfSiO₄, MgO, and Si₃N₄.

6. The integrated circuit of claim 4, wherein the at least one layer comprises oxygen and one or more of titanium, barium, lanthanum, hafnium, zirconium, tantalum, strontium, yttrium, calcium, aluminum, and magnesium.

7. The integrated circuit of claim 4, wherein the at least one layer comprises:
oxygen, silicon, and one or more of hafnium and zirconium; or
nitrogen and silicon.

8. The integrated circuit of claim 4, wherein the at least one layer comprises a plurality of superlattice sub-layers, the plurality including first and second sub-layers each comprising a superlattice structure with high-K dielectric properties.

9. The integrated circuit of claim 8, wherein the superlattice structure for each of the first and second sub-layers comprises a bilayer structure of PbTiO₃ and SrTiO₃.

10. The integrated circuit of claim 3, wherein each layer of the stack of layers has a thickness of between 1 nm and 50 nm.

11. The integrated circuit of claim 1, wherein an amount of capacitance provided by the at least one capacitance structure is sufficient to prevent full discharge of the one or more bit lines during a functional read spanning more than 150 picoseconds.

12. The integrated circuit of claim 1, wherein an amount of capacitance provided by the at least one capacitance structure is between 10 aF and 100 fF.

13. The integrated circuit of claim 12, wherein the amount of capacitance provided by the at least one capacitance structure is between 40 fF and 70 fF.

14. The integrated circuit of claim 12, wherein the amount of capacitance provided by the at least one capacitance structure is between 30 aF and 100 aF.

15. A capacitance-loaded static random-access memory (C-SRAM) comprising the integrated circuit of claim 1.

16. A processor comprising the C-SRAM of claim 15.

17. A capacitance-loaded static random-access memory (C-SRAM) comprising:
an array of SRAM bit cells coupled to one or more bit lines; and
a plurality of capacitance structures, each capacitance structure of the plurality of capacitance structures being coupled to a corresponding SRAM bit cell of the array of SRAM bit cells.

18. The C-SRAM of claim 17, wherein each capacitance structure of the plurality of capacitance structures is disposed in a back end of line of the C-SRAM.

19. The C-SRAM of claim 17, wherein an amount of capacitance provided by each capacitance structure of the plurality of capacitance structures is between 10 aF and 100 fF.

20. The C-SRAM of claim 17, wherein an amount of capacitance provided by the plurality of capacitance structures is between 10 aF and 100 fF.

21. The C-SRAM of claim 20, wherein the amount of capacitance provided by the plurality of capacitance structures is between 30 aF and 100 aF.

22. A method of forming a capacitance-loaded static random-access memory (C-SRAM) bit cell, the method comprising:
forming an access transistor in a front end of line of the C-SRAM;
forming at least one interconnect coupled to the access transistor;
forming a metal layer coupled to the at least one interconnect, the metal layer housing at least one bit line; and
forming, in a back end of line of the C-SRAM, a capacitance structure coupled to the metal layer.

23. The method of claim 22, wherein forming the capacitance structure comprises forming a plurality of capacitance structures.

24. The method of claim 23, wherein forming the plurality of capacitance structures comprises forming each capacitance structure of the plurality of capacitance structures to comprise a plurality of layers.

25. The method of claim 24, wherein forming each capacitance structure to comprise the plurality of layers comprises forming each layer of the plurality of layers to have a thickness of between 1 nm and 50 nm.
